(19) United States
(12) Patent Application Publication
(10) Pub. No.: US 2025/0087441 A1
(43) Pub. Date: Mar. 13, 2025

(54) ADJUSTABLE MULTIPLE FILAMENT ION BEAM DEPOSITION SYSTEM

(71) Applicant: INTEVAC, INC., Santa Clara, CA (US)

(72) Inventor: Thomas P. Nolan, Fremont, CA (US)

(21) Appl. No.: 18/367,839

(22) Filed: Sep. 13, 2023

(51) Int. Cl. H01J 37/08; C23C 16/48; C23C 16/52; H01J 37/317

(52) U.S. Cl. CPC H01J 37/08; C23C 16/486; C23C 16/52; H01J 37/3178; H01J 2237/0822

(57) ABSTRACT

A chemical vapor deposition chamber including a vacuum chamber; a power source; a gas conduit coupling the vacuum chamber to a precursor gas source; a filament arrangement energized by the power source to thereby impart thermal energy to molecules of precursor gas flowing from the precursor gas source; a coupling mechanism; wherein the filament arrangement comprises a plurality of filaments and the coupling mechanism electrically coupling the power source only to a subset of the plurality of filaments at any given time, while remaining filaments are not energized.

### BACKGROUND

### 1. Field

This disclosure relates to systems for forming thin layers on substrates using ion source or hot filament chemical vapor deposition.

### 2. Related Art

Traditional chemical vapor deposition (CVD) chambers decompose precursor gases to thereby form desired thin films on a substrate. Examples of CVD chambers are disclosed in U.S. Pat. No. 6,284,312, WO2016/024361 and WO2010/008477. A hot filament electron generator and magnetic fields may be utilized to “crack” or ionize the precursor gas, to thereby deposit specified material layer on a substrate, e.g., a semiconductor, a magnetic hard disk, etc. When ionized species are accelerated in an electric field before being neutralized and deposited, it is often referred to as an ion source or ion beam deposition.

In one example, hard overcoat layers are deposited on magnetic disks forming recording media. The depositions of such hard coatings have required optimally uniform layers, generally between 1-10 nm thick. Such deposition processes must be stable for the maximum number of cycles before maintenance. As tolerances become tighter, film uniformity over the substrate must be maintained over hundreds of thousands of substrates. For example, nominally 2 nm thick films require circumferential and radial uniformity of within 0.2 nm or less. Unfortunately, over this duration, the filaments commonly used in these systems degrade and warp or sag over time, which produces asymmetry and non-uniformity in the resulting deposition profile.

Many different filament designs and geometries have been employed to mitigate this problem, but all suffer from this time-dependent asymmetry. One approach attempting to address this problem is disclosed in the above-cited WO2016/024361, which uses filament made by braiding wires of tantalum and tungsten. The synthesis and growth of diamond can be achieved by using filaments of very high temperatures, e.g., 2400° C. In one example, JP2019094516 discloses utilizing filament layers that are arranged in a plurality of stages at predetermined intervals to achieve the required high temperature deposition. However, JP2019094516 fails to address the issue of filament deterioration over multiple process cycles.

As technology advances and the requirements of the various deposited layers change, the requirement for film uniformity remains paramount. Therefore, solutions are needed to address the degradation of the filament, especially such degradation as changes in shape that lead to non-uniformity of the formed films.

### SUMMARY

The following summary of the invention is included in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Disclosed embodiments provide a filament arrangement that compensates for the deterioration of the filament due to high temperatures. The disclosed embodiments provide an arrangement employing multiple filaments positioned at different orientations with respect to the gravity pull direction. Disclosed embodiments also provide arrangement having multiple filaments that are energized serially in time, so as to distribute the workload among the filaments.

Disclosed embodiments further provide a multi-filament processing module, comprising: an encasing forming a gas conduit; a plurality of filaments mounted within the conduit and positioned to intercept gas flowing within the conduit; a power source; and a coupling mechanism, e.g., a switching coupler, coupling the power source to a subset of the plurality of filaments at any given instance. The switching coupler may be implemented using various technologies and topographies, including, e.g., a crossover switch or a matrix switch using mechanical or solid-state implementations.

In a related aspect, disclosed embodiments provide a chemical vapor deposition chamber including a vacuum chamber; a power source; a gas conduit coupling the vacuum chamber to a precursor gas source; a filament arrangement energized by the power source to provide an electron source to the chamber and impart thermal energy to molecules of precursor gas flowing from the precursor gas source; a switching coupler; wherein the filament arrangement comprises a plurality of filaments and the switching coupler electrically coupling the power source only to a subset of the plurality of filaments at any given time, while remaining filaments are not energized.

Additionally, a method for energizing the filaments in a chemical vapor deposition system having a plurality of filaments for cracking precursor gas is disclosed, comprising: energizing a first subset of the plurality of filaments; after a prescribed period of time has passed, energizing a second subset of the plurality of filaments.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements and are not drawn to scale.

FIGS. 1A-1D are general schematics of a vertically and horizontally oriented filaments according to the prior art.

FIG. 2A is a general schematic of a vertically and horizontally oriented filaments positioned to intercept precursor gas, according to an embodiment, while FIG. 2B is a general schematic of a vertically and horizontally oriented filaments positioned to intercept precursor gas, according to another embodiment.

FIG. 2C is a general schematic of a brush contact.

FIG. 3 is a general schematic of a vertically and horizontally oriented filaments positioned to intercept precursor gas, according to yet another embodiment.

FIGS. 4A-4D illustrate embodiments having multiple filaments.

FIG. 5 is a general schematic of a processing system that includes a processing chamber utilizing the multiple filaments arrangement according to any of the embodiments disclosed herein.

FIG. 6 illustrates a flow chart of a processing that can be performed to energize filaments of a multi-filament module according to disclosed embodiments.

FIG. 7 illustrates another flow chart of a processing that can be performed to energize filaments of a multi-filament module according to disclosed embodiments.

FIG. 8 illustrates yet another flow chart of a processing that can be performed to energize filaments of a multi-filament module according to disclosed embodiments.

### DETAILED DESCRIPTION

Embodiments of the inventive filament arrangements will now be described with reference to the drawings. Different embodiments may be used for processing different substrates or to achieve different benefits, such as throughput, film uniformity, target utilization, etc. Depending on the outcome sought to be achieved, different features disclosed herein may be utilized partially or to their fullest, alone or in combination with other features, balancing advantages with requirements and constraints. Therefore, certain features and benefits will be highlighted with reference to different embodiments, but are not limited to the disclosed embodiments, and the features may be incorporated in other embodiments or with other combinations.

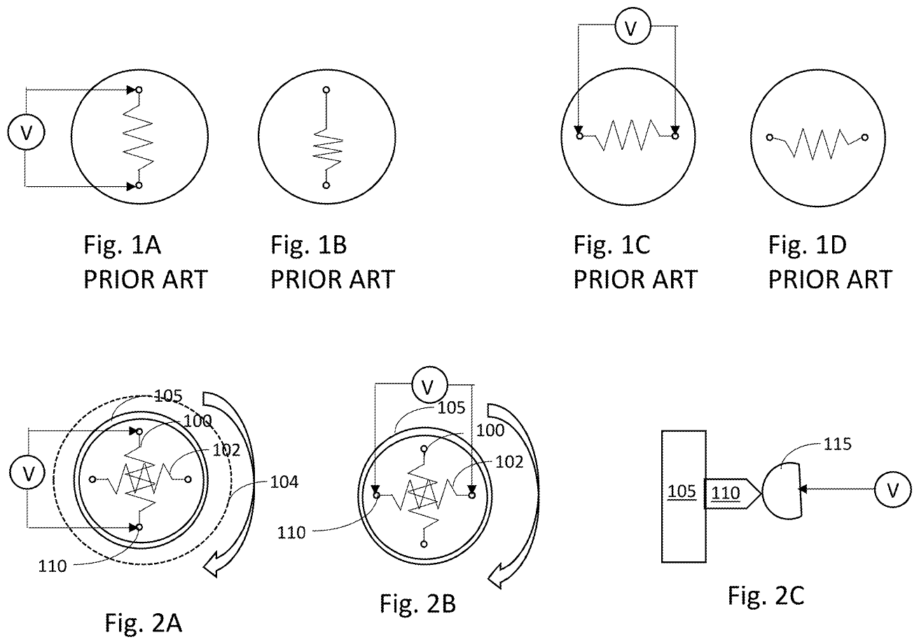

FIG. 1A illustrates a filament of the prior art, which is shown oriented vertically. Over time during service, mainly due to pull of gravity and high temperature operation, the filament sags, as shown in FIG. 1B. It may also locally change diameter and resistance along its path causing patterns of non-uniform heating and electron emission. Similarly, FIG. 1C illustrates a filament of prior art in horizontal orientation, which over time sags, as shown in FIG. 1D. Such sagging leads to non-uniformity of the film deposited on the substrate, since the heat generated by the sagging filament is not uniform, such that dissociation of gas in one area of the chamber is higher than in other areas. Consequently, periodic maintenance and filament replacement is required, which reduces the output of the deposition system. Prior attempts at improving film uniformity and extending the service life of the filament focused mainly on the filament material composition or structure. However, even with improved filaments of the prior art, there is still a need to further extend the service life of sufficiently uniform film deposition in between required periodic maintenance.

The following disclosure includes embodiments of unique arrangements that improve performance and extend the service life of the chamber in between required maintenance. The presented solutions can utilize any of the filaments of the prior art, utilizing any compositional materials and structures. Various disclosed embodiments utilize multiple filaments, where only a portion of the available filaments are energized at a time or the filaments are energized to different levels at different times during operation.

FIG. 2A illustrates a first embodiment wherein two filaments, 100 and 102, are mounted onto a rotatable ring 105. This arrangement of filaments and rotating ring is mounted within an encasing that forms a gas conduit between the gas source and the chamber void where the substrate is processed, generally shown in dotted line circle 104. The arrangement is positioned to provide emissions that intercept precursor gas flowing within the gas conduit so as to crack the precursor gas. One filament, here 100 is oriented vertically, while another filament 102 is oriented horizontally. In this embodiment vertically oriented contacts or contact points are connected to a power source V, such that only the filament that is oriented vertically is energized. As shown by the curved arrow, the rotatable ring 105 can be rotated so as to place any of filaments 100 or 102 in the vertical position, and thereby be energized. Thus, at any given time, only one of the filaments is energized, while the other filament is not operational. In operation, an operator or a computerized controller may periodically rotate ring 105 so as to use different filament periodically. Consequently, the service period in between required maintenance is elongated.

In a similar manner, FIG. 2B illustrates an embodiment wherein the active, energized filament is positioned horizontally. In this embodiment, filament 102 is shown in the horizontal position and coupled to the power source. Ring 105 can be rotated so as to place filament 100 in the horizontal orientation and coupled to the power source. In this embodiment as well, at any given time only one of the filaments is energized, while the other filament is not operational.

In any of the embodiments disclosed herein, the switching of the connections to the power source can be implemented mechanically by, e.g., the use of contact points, such as brush contacts. A brush contact or carbon brush contact is an electrical contact which conducts current between stationary contact and a moving contact, e.g., a rotating shaft of a motor or generator. In the embodiments of FIGS. 2A and 2B, the moving part is the rotating ring 105, upon which the brush contact is installed, as exemplified in FIG. 2C. Specifically, a small section of ring 105 is shown from the side. Bruch contact 110 is shown mounted onto the section of the ring 105 and contacting the stationary contact 115. The stationary contact is connected to the power source.

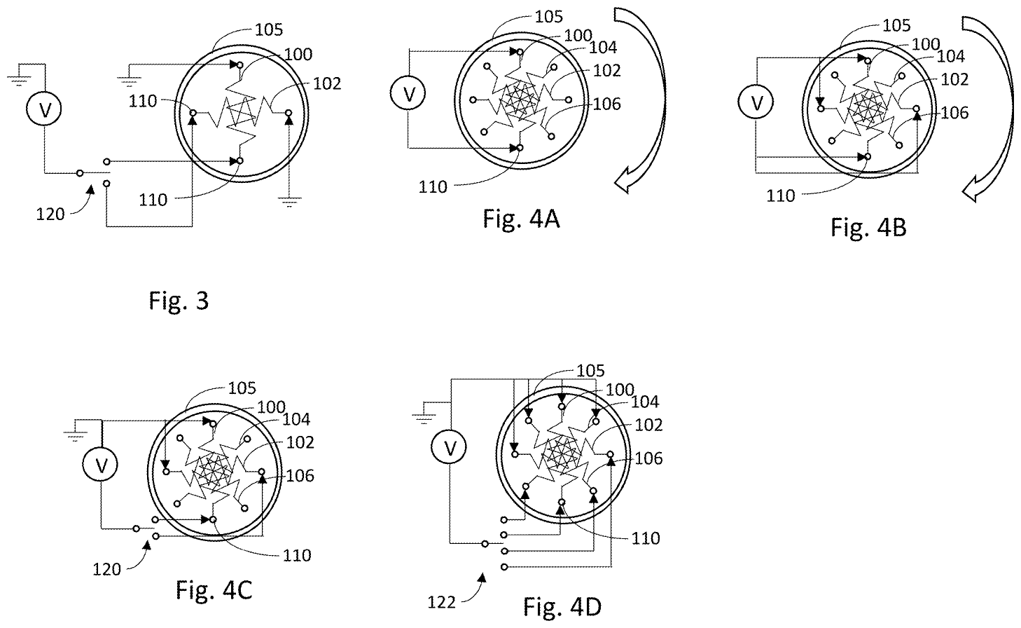

FIG. 3 illustrates another embodiment, wherein either the vertically oriented filament 100 or the horizontally oriented filament 102 can be energized at a time, using a switching arrangement 120. This embodiment can be utilized by energizing one of the filaments 100 or 102 during processing of one substrate, and alternating to the other filament during processing of the next substrate. Conversely, the two filaments can be energized alternatingly during the processing of a single substrate, so as to create a more uniform dissociation of the precursor gas flowing around the filaments. According to a more likely scenario, one filament is used consistently for multiple processes, and the switch to the other filament occurs after a predetermined number of substrates has been processed, e.g., after more than 10,000 substrates have been processed, or the switch occurs after an external post-processing test of uniformity of the deposited layer on the substrate fails a prescribed specification-independent of number of processing cycles.

FIG. 4A illustrates an embodiment wherein multiple filaments are installed on rotating ring 105. Here four filaments are shown 100, 102, 104 and 106, but any number of filaments can be employed. Also, in this embodiment only one of the filaments can be energized at any given time. Conversely, FIG. 4B illustrates an embodiment utilizing multiple filaments wherein a subset of the available filaments is energized at any given time. In the example of FIG. 4B the vertical and horizontal oriented filaments are energized, while all other filaments are not energized.

FIG. 4C illustrates an embodiment utilizing multiple filaments that are energized in a manner similar to that of FIG. 3. That is, the filaments may be attached in a rotatable or fixed orientation. A switch 120 is provided to enabling energizing only a subset of the available filaments at any given time. For example, FIG. 4C illustrates an embodiment wherein the filaments placed in the vertical or horizontal positions can be energized at any given time, but the ring 105 can be rotated to replace the filaments that occupy the vertical and horizontal positions.

FIG. 4D illustrates a multi filament embodiment which utilizes a multi-point switch 122, such as a solid-state switch, to energize a subset of the filaments at any given time. For example, the switch 122 can be operated in a round-robin fashion, thereby energizing the filaments one after the other-thus distributing the workload among the available filaments. This embodiment can be implemented with stationary ring 105, and when utilizing a solid-state switch, it minimizes mechanically moving parts in the system. The multi-point selector switch is sometimes referred to as multi-position switch, wherein its distinguishing feature is that it has more than two positions, as opposed to a standard selector switch which has only two positions, e.g., on and off, as shown by switch 120 of FIG. 4C.

Thus, in the disclosed embodiments a chemical vapor deposition chamber is provided, which includes a vacuum chamber coupled to a precursor gas source. A filament arrangement is provided to impart thermal energy to molecules of the precursor gas. The filament arrangement includes a plurality of filaments, a switching arrangement and a power source. The switching arrangement electrically couples the power source to a subset of the plurality of filaments at any given time. In some embodiments the switching arrangement comprises a rotating ring upon which the filaments are attached. The rotating ring may include contact points and/or brushes. In some disclosed embodiments the switching arrangement includes a switch, such as a multi-point switch or a solid-state switch. As described in more details further below, the switching arrangement may also apply different power levels to different filaments, rather than a simple on/off switching. Accordingly, in this disclosure all such examples and implementations may be referred to herein as a “switch” or “switching coupler”.

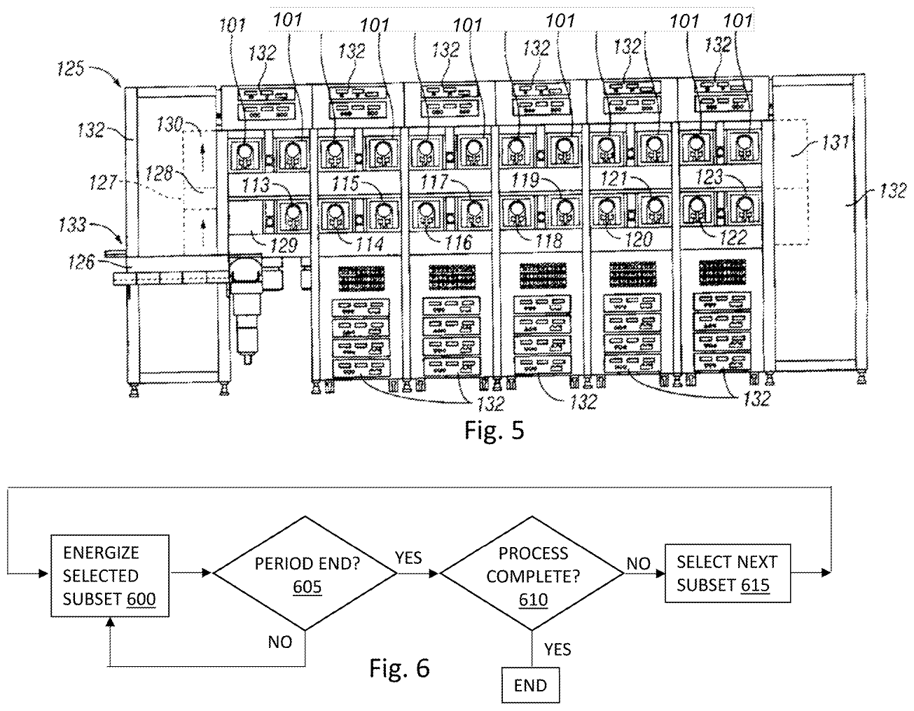

FIG. 5 illustrates a vacuum processing system, such as the one disclosed in U.S. Pat. No. 6,919,001 commonly assigned to the subject assignee. For a complete disclosure of the system the reader is directed to the '001 patent. The system is composed of multiple processing chambers in a two level linear arrangement. The chambers of the top row are labeled 101 while the chambers of the bottom row are labeled 113-129. Elevator 125 transfers substrate carriers between the bottom and top rows of chambers. Each of the processing chambers may be fitted with a processing module to perform a given process, such as etching, heating, sputtering deposition, chemical vapor deposition, etc., such that as the substrate progresses along the system different processes are performed on the substrate to form various thin film layers on the substrate. Depending on the processes to be performed, any of the chambers may be fitted with any of the multi-filament modules as disclosed herein.

FIG. 6 illustrates a flow chart of a processing that can be performed to energize filaments of a multi-filament module according to disclosed embodiments. In step 600 a subset of the plurality of filaments is energized. A prescribed time period is then monitored at 605. When the time period has passed, optionally at 610 it is checked whether the processing of the substrate has completed and, if it completed, the process ends. If processing has not been completed, at 615 another subset of the filaments is selected and then the process reverts to 600 by energizing the newly selected subset. It should be appreciated that the total number of filaments may be divided into two subsets in some embodiments, or to more than two subsets in other embodiments. However, in either case, only a subset of the total number of filaments is energized.

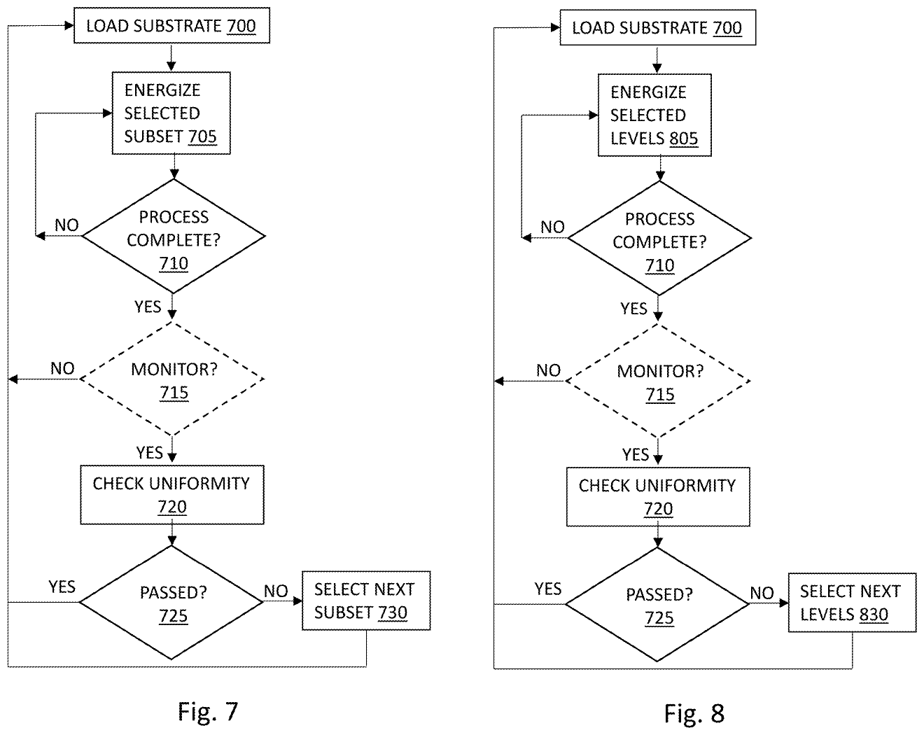

FIG. 7 illustrates a process wherein the switch to another subset of filaments is performed according to the monitoring of processing results. In one example, each substrate is checked after processing to verify the deposited layer's uniformity, while in another example a monitoring number or period is set, such that the check is performed after a preset number of substrates has been processed or after a preset time period has passed. In this example, the process starts by loading a substrate at step 700 and energizing the selected subset at step 705. When processing of the loaded substrate is completed at 710, if a monitoring number or period is set, then at 720 the uniformity of the deposited layer is checked. Step 715 is shown in dashed-line since if the uniformity check is to be performed on every substrate, then step 715 can be bypassed and the processed may proceed from step 710 to step 720 directly. In step 725 if the uniformity is within prescribed specification, the process may continue with the same subset of filaments. On the other hand, if at step 725 the uniformity is not within the specification, at step 730 the nest subset of filaments is selected and the process proceeds.

According to further embodiments, a subset (or the superset) of the filaments can be energized, while the power level to each filament is changed in analog fashion (e.g., gradually increase or decrease with time or per defined period) so as to define an adjustable filament temperature for each filament within the subset or superset. According to an example, all of the filaments within the subset or the superset are energize to some degree at all times, as opposed to requiring the binary change of energizing or not energizing different subsets of filaments such that at least one filament is completely off. In such embodiments, whenever implementing the processes such as the processes exemplified in FIGS. 6 and 7, when the process indicates the switch to a different substrate, the process instead changes the distribution of energy levels to the different filaments. Such an example is illustrated in FIG. 8, wherein generally the process mimics the process of FIG. 7, except that in step 805 the filaments are energized according to a programmed level, such that each filament is energized to a prescribed level (which may include zero). Also, in step 830, when the uniformity is determined to be outside of the specification, the next prescribed power level distribution is selected.

While the disclosed embodiments are described in specific terms, other embodiments encompassing principles of the invention are also possible. Further, operations may be set forth in a particular order. The order, however, is but one example of the way that operations may be provided. Operations may be rearranged, modified, or eliminated in any particular implementation while still conforming to aspects of the invention.

All directional references (e.g., upper, lower, upward, downward, left, right, leftward, rightward, top, bottom, above, below, etc. are only used for identification purposes to aid the reader's understanding of the embodiments of the present invention, and do not create limitations, particularly as to the position, orientation, or use of the invention unless specifically set forth in the claims. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

In some instances, components are described with reference to “ends” having a particular characteristic and/or being connected to another part. However, those skilled in the art will recognize that the present invention is not limited to components which terminate immediately beyond their points of connection with other parts. Thus, the term “end” should be interpreted broadly, in a manner that includes areas adjacent, rearward, forward of, or otherwise near the terminus of a particular element, link, component, member or the like. It is intended that all matter contained in the above description or shown in the accompanying drawings shall be interpreted as illustrative only and not limiting. Changes in detail or structure may be made without departing from the spirit of the invention as defined in the appended claims.

It must be noted that as used herein and in the appended claims, the singular forms “a”, “an”, and “the” include plural referents unless the context clearly dictates otherwise.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention.

What is claimed is:

1. A multi-filament processing module, comprising:
an encasing forming a gas conduit;
a plurality of filaments mounted within the conduit and positioned to intercept gas flowing within the conduit;
a power source; and
a switching coupler coupling the power source to a subset of the plurality of filaments at any given instance.

2. The module of claim 1, wherein the switching coupler comprises a rotating ring having a plurality of contacts electrically connected to the plurality of filaments.

3. The module of claim 2, further comprising a plurality of brush contacts, wherein the number of the plurality of brush contacts is less than the number of the plurality of contacts electrically connected to the plurality of filaments.

4. The module of claim 2, further comprising a switch interposed between the power source and the plurality of contacts.

5. The module of claim 1, wherein the switching coupler comprises a switching arrangement interposed between the power source and the plurality of filaments.

6. The module of claim 5, wherein the switching coupler comprises a multi-point switch having more than two contact positions.

7. The module of claim 6, wherein the multi-point switch is a solid-state switch.

8. The module of claim 5, wherein the switching coupler comprises a selector switch having a first position electrically coupled to the subset of the plurality of filaments, and a second position electrically coupled to the remainder of the plurality of filaments.

9. The module of claim 1, wherein the switching coupler and power source generate different power settings to be applied to the subset of the plurality of filaments at any given instance.

10. A vacuum processing system, comprising:
a plurality of vacuum processing chambers, wherein at least one of the plurality of vacuum processing chambers comprises:
a vacuum chamber;
a power source;
a gas conduit coupling the vacuum chamber to a precursor gas source;
a filament arrangement energized by the power source to thereby impart thermal energy and energetic electrons to molecules of precursor gas flowing from the precursor gas source;
a switch;
wherein the filament arrangement comprises a plurality of filaments and the switch electrically couples the power source to at least one of the plurality of filaments at any given time.

11. The system of claim 10, wherein the switch electrically couples the power source to only a subset of filaments at any given time, while remaining filaments are not energized.

12. The system of claim 10, wherein the switch electrically couples the power source to at least two subsets of filaments energized at different power levels.

13. The system of claim 10, further comprising a rotating ring having a plurality of contacts electrically connected to the subset of the plurality of filaments.

14. The system of claim 13, further comprising a plurality of brush contacts arranged to engage the plurality of contacts electrically connected to the subset of the plurality of filaments.

15. The system of claim 13, wherein the switch is interposed between the power source and the plurality of contacts.

16. The system of claim 10, wherein the switch comprises a plurality of outputs applying different levels of output power from the power source to the plurality of filaments.

17. The system of claim 16, wherein the switching arrangement comprises a multi-point switch having more than two contact positions.

18. The system of claim 17, wherein the multi-point switch is a solid-state switch.

19. The system of claim 16, wherein the switch comprises a selector switch having a first position electrically coupled to the subset of the plurality of filaments, and a second position electrically coupled to the remainder of the plurality of filaments.

20. In a chemical vapor deposition system having a plurality of filaments for cracking precursor gas, a method for energizing the filaments, comprising:
energizing a first subset of the plurality of filaments at a first power level;
after a prescribed period of time has passed, energizing a second subset of the plurality of filaments at a second power level.

21. The method of claim 20, wherein the first subset and the second subset constitute the entire plurality of filaments.

22. The method of claim 20, further comprising after a prescribed period of time has passed, energizing a third subset of the plurality of filaments at a third power level.

23. The method of claim 20, wherein the first subset and the second subset are interchangeably energized a plurality of times during processing of a single substrate.

24. The method of claim 20, wherein the first power level and the second power level are equal power levels.

25. The method of claim 22, wherein the first power level, the second power level and the third power level are different power levels.
